(19) United States
(12) Patent Application Publication
(10) Pub. No.: US 2009/0042339 A1
(43) Pub. Date: Feb. 12, 2009

(54) PACKAGED INTEGRATED CIRCUITS AND METHODS TO FORM A PACKAGED INTEGRATED CIRCUIT

(75) Inventors: Saat Shukri Embong, Selangor (MY); Suhairi Mohmad, Kuala Lumpur (MY); Mohd Hanafi Bin Mohd Said, Selangor (MY)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/837,147

(22) Filed: Aug. 10, 2007

(51) Int. Cl. H01L 21/00

(52) U.S. Cl. 438/123; 29/827; 257/784; 257/E23.06

(57) ABSTRACT

Packaged integrated circuits and methods to form a packaged integrated circuit are disclosed. A disclosed method comprises attaching an integrated circuit to a substrate, coupling a first end of a bond wire directly to the substrate without an intervening bonding pad and a second end of the bond wire to a contact of the integrated circuit, encapsulating the integrated circuit and the bond wire, and removing the substrate to expose the first end of the bond wire.

### TECHNICAL FIELD

The present disclosure pertains to integrated circuits and, more particularly, to packaged integrated circuits and methods to form a packaged integrated circuit.

### BACKGROUND

In many electrical devices and systems, an integrated circuit is not directly attached to a circuit board. Rather, the integrated circuit (IC) is packaged into a housing to facilitate interfacing the integrated circuit with the circuit board and to protect the integrated circuit from the environment. Generally, a packaged integrated circuit is attached to the circuit board of the electrical device or system via contacts (e.g., electrical leads, etc.) of the packaged IC. For example, each contact of the integrated circuit is soldered to a contact of the circuit board.

To manufacture a packaged integrated circuit, an integrated circuit (e.g., a device or a circuit such as a power amplifier, processor, etc.) is attached to a substrate or a leadframe. Leadframes come in many forms. For example, a leadframe land grid array (LLGA) is a laminate substrate with exposed bonding pads. To create such a leadframe, a resist layer mask is applied to a substrate to mask a portion of the leadframe. A plating process forms the metal contacts beneath the resist layer mask (e.g., on areas of the substrate which are not exposed by the mask). The resist layer mask is then removed to expose the substrate and the metal contacts. When the leadframe is ready for packaging, the IC is attached to the leadframe using a mounting technique (e.g., epoxy, eutectic, etc.). Bond wires (e.g., aluminum, gold, copper, etc.) are placed from the bonding pads to the IC using a wire bonding technique (e.g., stitch bond, wedge bond, etc.) and a wire. After placing the bond wires, a molding process is applied to the leadframe to encapsulate the IC and the bond wires in a mold. As a result, the IC is encapsulated in a rigid housing which protects the IC. After the molding, the substrate is removed to expose the metal pads to facilitate mounting of the packaged IC to a circuit board.

### SUMMARY

Packaged integrated circuits and methods of manufacturing a packaged integrated circuit are described. In some example methods, an integrated circuit with contacts is attached to a substrate without forming metal contacts on the substrate. After attaching the integrated circuit to the substrate, a bond wire is placed to couple the substrate with a contact of the integrated circuit. After the bond wire is placed, a container is formed over the integrated circuit and bond wires to encapsulate the integrated circuit and the bond wire. Finally, the substrate is removed to form a packaged integrated circuit. Because the bond wire was bonded to the substrate, a portion of the bond wire is exposed on the packaged integrated circuit to form a contact of the packaged integrated circuit.

### BRIEF DESCRIPTION OF THE DRAWINGS

FIG. 1 is an illustration of an example packaged integrated circuit.

FIG. 2 is a flowchart representative of an example process to create the example packaged integrated circuit of FIG. 1.

FIGS. 3A-G are illustrations of an example semiconductor device at different stages of the example process of FIG. 2.

FIG. 4A is a flowchart representative of an example process to place a stand-off-stitch bond.

FIGS. 4B-E are illustrations of a stand-off-stitch bond at different stages of the example process of FIG. 4A.

FIG. 5 illustrates another substrate used in the example process of FIG.

FIG. 6 is a flowchart representative of another example process to create an example packaged integrated circuit with a heat sink.

FIG. 7 is a flowchart representative of another example process to form an example packaged integrated circuit.

FIG. 8 illustrates another substrate used in the example process of FIG. 7.

To clarify multiple layers and regions, the thickness of the layers are enlarged in the drawings. Wherever possible, the same reference numbers will be used throughout the drawing(s) and accompanying written description to refer to the same or like parts. As used in this patent, stating that any part (e.g., a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

Packaged integrated circuits and methods to form a packaged integrated circuit will now be disclosed. As described herein, an integrated circuit is a die or a chip containing at least one active semiconductor device (e.g., an NPN transistor, etc.). Thus, for example, an integrated circuit may contain a single active device (e.g., a transistor) or the integrated circuit may contain multiple active devices (e.g., a processor having millions of transistors).

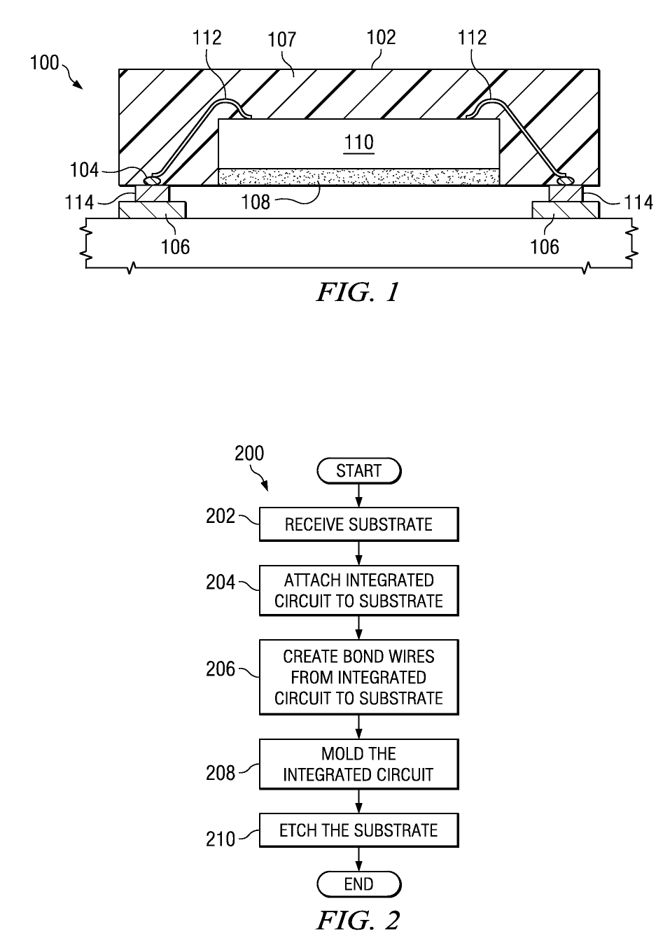

FIG. 1 is an illustration of an example semiconductor device 100 having a packaged integrated circuit 102. The semiconductor device has a circuit board 104 with a plurality of contacts 106 for receiving devices and components (e.g., capacitors, inductors, integrated circuits, resistors, etc.). The packaged integrated circuit 102 includes a mold 107 and a bonding layer 108. An integrated circuit 110 sits above the bonding layer 108. The mold 107 is made of any material suitable to securely contain the devices associated with the packaged integrated circuit 102 (e.g., a plastic, an epoxy, etc.). To interface the integrated circuit 110 with the external components and devices of the example electronic device 100, a plurality of bond wires 112 are included. In the example of FIG. 1, a portion of the example bond wires 112 are exposed at the surface of the packaged integrated circuit 102. In other words, a portion of the bond wires 112 form the contacts of the integrated circuit 110. To attach the integrated circuit 110 with the contacts 106 of the circuit board 102, an attaching material 114 (e.g., solder) is applied between the contacts 106 and the exposed portion of the bond wires 112.

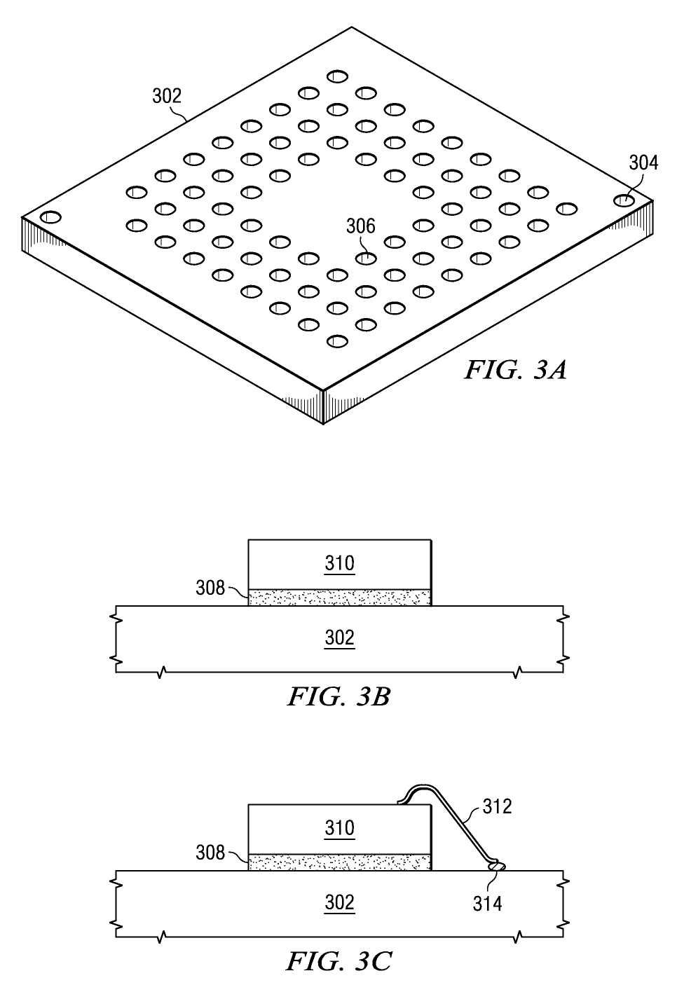

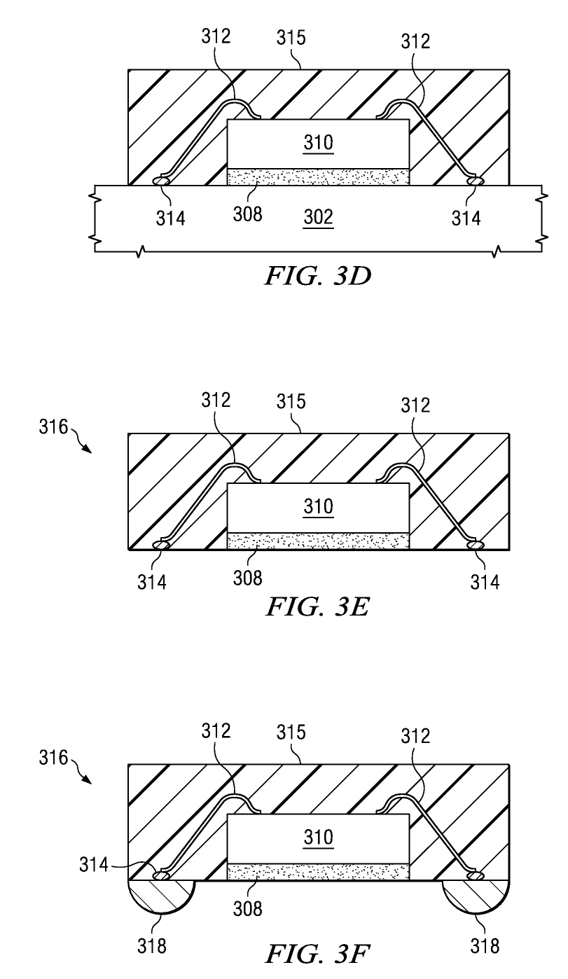

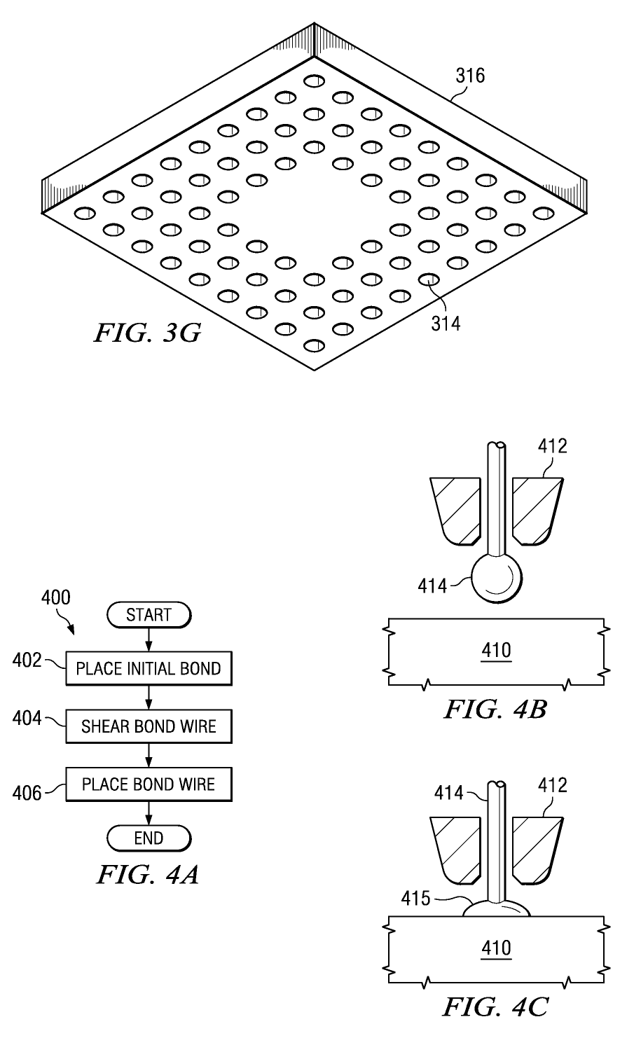

FIG. 2 is a flow chart representing an example process 200 to form a packaged integrated circuit (e.g., the packaged integrated circuit 110 of FIG. 1). In the example of FIG. 2, the example process 200 begins by selecting a substrate (block 202). FIG. 3A illustrates an example substrate 302 used for the example process 200. The example substrate 302 may be implemented by any material suitable for a packaging process (e.g., a copper alloy, an aluminum alloy, etc.). The substrate 302 of the illustrated example has a tooling hole 304 to align the substrate 302 with any tooling equipment used in the example process 200 (e.g., a wire bonder, a die attacher, etc.). In addition, the substrate 302 may include a plurality of fudicial marks 306 to identify the locations where the bond wires may be placed.

After the substrate 302 is selected, an integrated circuit (IC) is attached to the substrate 302 (block 204) using any technique (e.g., epoxy, eutectic, solder, etc.). In the example of FIG. 3B, the IC 310 is attached to the substrate 302 by applying a layer of epoxy 308 to the substrate 302 and placing the integrated circuit 310 on the epoxy layer 308. The epoxy layer 308 is then processed (e.g., heated) to couple the integrated circuit 310 with the substrate 302.

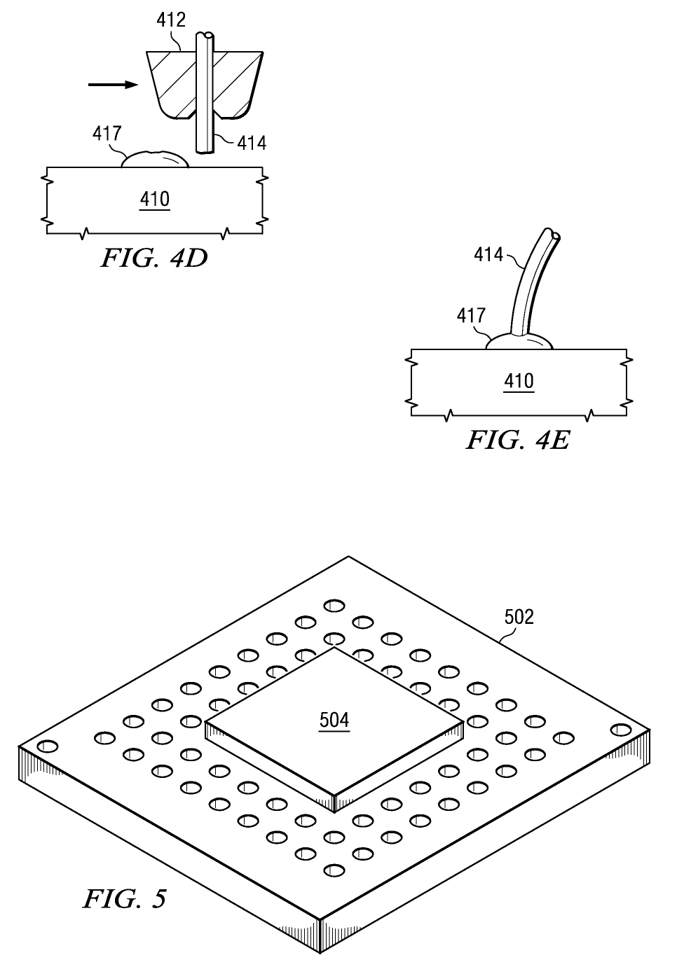

After the integrated circuit 310 is attached to the substrate 302 (block 204), a plurality of bond wires 312 are placed to couple the substrate 302 with the contacts of the integrated circuit 310 (block 206). In the example of FIG. 3C, an example bond wire 312 couples the bond wire 312 directly to the substrate 302 via a stand-off-stitch bond without an intervening bonding pad. However, any type of wire bond technique may be used to couple the bond wire 312 directly with the substrate 302 with the integrated circuit 110 (e.g., bell bond, wedge bond, a reverse stand-off-stitch bond, etc.) using any type of bond wire material (e.g., gold, copper, aluminum, etc.). The example stand-off-stitch bond wire 312 of FIG. 3C may be placed in the method described below in connection with FIG. 4A. In the illustrated example, a stud 314 at one end of the bond wire to increase the surface area of the bond. In addition, the fudicial marks 306 of the substrate 302 identify the location where the studs 314 of the bond wire 312 are placed.

After all bond wires 312 are coupled from the substrate 302 to the integrated circuit 310, a molding process is applied to the substrate 302 to form a mold 315 over the integrated circuit 310 and bond wires 312 (block 208). In the illustrated example, a mold 315 is a material that encapsulates and seals the integrated circuit 310. Generally, the mold 315 may be implemented by any suitable material to protect the integrated circuit 310 and bond wires 312 (e.g., an epoxy, a ceramic, a plastic material, etc.) from the environment. In the example of FIG. 3D, after the mold 315 is formed, the integrated circuit 310 and the bond wires 312 are encapsulated inside of the mold 315 and cannot move. Thus, the molding process seals and protects both the bond wires 312 and the integrated circuit 310 from the environment. For example, prior to the molding process, the bond wires 312 could be adjusted by contacting a bond wire. After the molding process (block 208), the bond wires 312 are encapsulated and shielded from movement by the mold 315.

After creating the mold 315 (block 208), the substrate 302 is removed to form a packaged integrated circuit 316 (block 210). In the example of FIG. 3E, the substrate 302 is removed via any suitable process which may be selected based on the material of the substrate. For example, an etch process may be implemented to remove the substrate without damaging the packaged integrated circuit 316. In some examples, the stud(s) 314 and the substrate 302 may be of different materials so that the etch process will not affect the bond wires 312. For example, if the substrate 302 is a copper alloy and the bond wire(s) 312 are gold, an etch process may remove the copper alloy without affecting the stud(s) 314 or the packaged integrated circuit 316. Because the bond wire(s) 312 were bonded directly to the substrate 312 (i.e., without an intervening bonding pad), a portion of the bond wire(s) 312 are exposed on a surface of the mold 315 after removing the substrate 302. In other words, the exposed portion(s) of the bond wire(s) 312 form the contact(s) of the packaged integrated circuit 316 and, thus, can be used to interface the integrated circuit 310 with one or more devices and one or more components. FIG. 3F illustrates an example packaged integrated circuit 316 with exposed contacts (e.g., bond wires 312) that form a grid array.

The example process 200 of FIG. 2 ends after the substrate 302 is removed. Although the foregoing describes a particular sequence of operations, the sequence of operations of the example process 300 may vary. For example, the stages of the process may be rearranged, combined, or divided. Alternatively or additionally, additional stages, processes or operations may be added. For example, a plating process may be implemented to form a standoff (e.g., a plate) above the contacts of the packaged integrated circuit to form a larger contact for the example packaged integrated circuit. In some examples, the plating process may create a stand-off so that the packaged integrated circuit rests above the surface (e.g., a printed circuit board, etc.). The plating process may be implemented by any technique (e.g., solder wave, screen print, etc.). In the example of FIG. 4F, a bumping process may form interconnect elements 318 (e.g., solder balls) that may be used attach the packaged integrated circuit to a surface (e.g., a printed circuit board, etc.). For example, a bumping process may be implemented to form a wafer level chip scale package (WLCSP). Alternatively or additionally, some or all of the materials described above may be changed.

As mentioned above, the example packaged integrated circuit of FIG. 3G is provided with contacts that form a grid array layout. However, the grid array is just one example configuration of a packaged integrated circuit. The contacts may be implemented to form any desired layout or configuration. For example, the example grid array layout could be modified to stagger the rows for maximum use of surface area. In other examples, a single row of contacts may be configured on two edges of the packaged integrated circuit, similar to a small outline package. Similarly, a single row of contacts may be configured on all four edges of the packaged integrated circuit. Because the placement of the bond wires define the form of the contact array, virtually any desired contact pattern can be achieved by selecting suitable locations for bonding the contact wires to the substrate. Thus, the example method of FIG. 2 provides great flexibility in developing packaged ICs.

FIG. 4A is flowchart illustrating an example process 400 to place a stand-off-stitch bond. As shown in the example of FIG. 4B, the example process 400 includes a substrate 410 and a wire bond tool 412 for placing a bond wire 414 on a substrate 410. In the example of FIG. 4B, a bond wire 414 includes a ball at the end of the bond wire. Initially, in the example of FIG. 4C, the bond wire tool 412 places an initial bond (e.g., a bell bond) 415 to couple the bond wire 414 with the substrate (block 402). The bond wire tool 412 shears the bond wire by moving horizontally to thereby leave a portion of the bond wire 414, or a stud 417. As shown in the example of FIG. 4D, the bond wire tool 412 rebonds the bond wire 414 on the top of the stud 417 to form a contact of the integrated circuit (block 406). Alternatively, the bond wire tool 412 may place the bond wire 414 by forming a bond (e.g., a ball bond) on the integrated circuit and placing a second bond (e.g., a stitch bond) on the stud 417. A stand-off-stitch bond may be implemented because the bond wire 414 may be very small (e.g., 1 mil diameter) the contact. However, the contact formed a stand-off-stitch bond illustrated in the example process 400 has a larger bonding area and thereby forms a larger contact of the packaged integrated circuit. Additionally, a stand-off-stitch bond may be used because the additional height of the stud 417 enables the wire bond tool 412 to place bond wires 412 with a lower loop height.

The example process 400 of FIG. 4 ends after the bond wire tool 412 places a bond from the stud 417 to the integrated circuit. Although the foregoing describes a particular sequence of operations with a single bond wire and a single tool, the materials, tools, and bond wires of the example process 400 may vary. For example, to form a larger contact for the packaged integrated circuit, a first tool may form the stud 417 with a bond wire 414 of any material (e.g., copper) having a first diameter (e.g., 5 mils). After forming the stud 417, a second tool may place the bond wire 414 between the stud 417 and the top of the integrated circuit. The second tool may be implemented to place a bond wire having a different diameter (e.g. 1 mil) than the stud 417 or a different material (e.g., gold, aluminum, etc.) than the stud 417. Persons having ordinary skill in the art will readily appreciate that different combinations of material or size or both may reduce costs, provide larger contacts, and so forth.

FIG. 5 illustrates an example a dual gauge substrate 502 (e.g., a substrate with two regions of different thicknesses) that may be used in the example process 200. In the example of FIG. 5, the dual gauge substrate 502 includes a raised portion 504 dimensioned to receive an integrated circuit. The raised portion 504 of the substrate 502 may be implemented from the same or a different material from the substrate 502 (e.g., a ceramic, a metal, a metal alloy, a plastic, etc.). In some examples, the substrate material is the same material as the bond wire material and the substrate is removed by the same (e.g., etch, etc.) or different processes (e.g., grind, etc.). For example, the substrate material may be removed by a half-etch process that does not remove the raised portion 504 of the substrate.

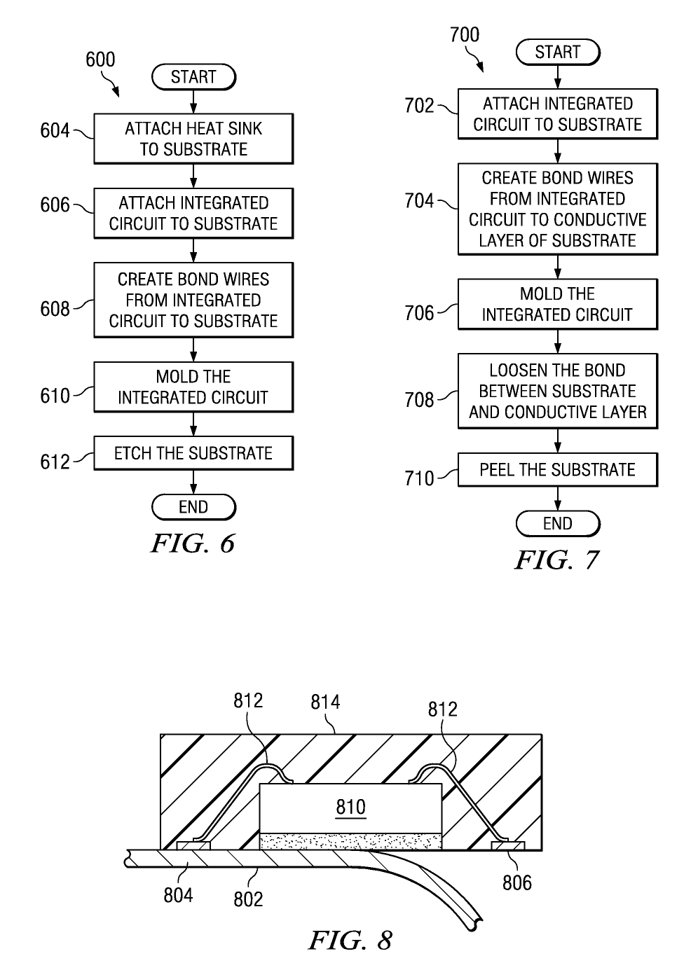

In some examples, a heat sink may be included in the packaged integrated circuit to facilitate thermal dissipation. The heat sink may be implemented by any material (e.g., copper, a copper alloy, aluminum, etc.). FIG. 6 illustrates another example process 600 to attach such a heat sink to an example integrated circuit package. The example process 600 begins by attaching a heat sink to a substrate (e.g., the example substrate of FIG. 3A, 4B, or 5A) using any technique (e.g., epoxy, solder, eutectic, etc.) (block 604). After the heat sink is attached, the integrated circuit is attached to the heat sink using any technique (block 606). Bond wires are then placed between the substrate and the integrated circuit as explained I the above examples (block 608). After all bond wires are placed, the molding process encapsulates the integrated circuit (block 610). An etch process then removes the substrate (block 612). Thus, in the example of FIG. 6, a surface of the packaged integrated circuit is exposed to reveal a portion of the heat sink and a portion of the bond wires.

FIG. 7 illustrates another example process 700 to form a packaged integrated circuit. In the example process 700 of FIG. 7, the substrate 802 may be implemented by a plastic material 704 selectively coated with a conductive layer 806 (e.g., a metal, a metal alloy, a conductive polymer, etc.) as shown in the example of FIG. 8. The plastic material 804 may be implemented by a high temperature material to prevent damage, melting, or any other deformation at high temperatures associated with the example process 700. The example process 700 begins by attaching an integrated circuit 810 to the substrate (block 702). After attaching the integrated circuit 810, bond wires 812 are then placed between the conductive layer 806 of the substrate 802 and the integrated circuit 810 (block 704). This may optionally be performed via an integrated heat sink as explained in connection with FIG. 6. After all bond wires 810 are created, the molding process encapsulates the integrated circuit in a mold 814 (block 706). Before removing the substrate 802, the bond between the substrate 802 and the conductive layer 806 may be loosened by any technique (e.g., heating the substrate 802 to a transition temperature, curing the substrate 802 with an ultraviolet light to loosen the bond between the substrate 802 and the conductive layer 806, etc.) (block 708). After loosening the bond between the substrate and the conductive layer (block 708), the substrate 802 is peeled away from the packaged integrated circuit (block 710). Thus, in the example of FIG. 7, the conductive layer 806 of the substrate 802 remains in-tact to form the contacts of the packaged integrated circuit.

In any of the above examples, a singulation process may also be employed to facilitate production. In such examples, multiple integrated circuits are attached to a single, large substrate. After following the process(es) to form a packaged integrated circuit (e.g., the example process of FIG. 2, 6, or 7), a plurality of packaged integrated circuits including multiple ICs attached to the same substrate is formed A mold is formed over the plurality of integrated circuits (e.g., either before or after removing the substrate). A singulation process is then used to divide the integrated circuits into individual packaged integrated circuits. The singulation process may be implemented by any suitable process to divide the packaged integrated circuits (e.g., a saw process, etc.).

In view of the foregoing, methods to manufacture a packaged integrated circuit with one or more contacts that are formed by one or more bond wires of the integrated circuit are disclosed. In the illustrated examples, the substrate of the packaged integrated circuit does not require leads. As a result, the substrate can be more rigid thereby simplify the handling and processing of developing packaged ICs. The illustrated example methods may be used to configure any desired layout of contacts (e.g., a grid array, a staggered grid array, a multirow, an outline, etc.) without any tooling or process changes. For example, the size of the contacts may be flexibly configured by selecting the bond wire size (i.e., the diameter of the bond wire) and the bond wire technique (e.g., a ball bond, a wedge bond, a ribbon bond, a stand-off-stitch bond, a bridge/clip bond, etc.). The pattern of the array can also be easily selected by choosing the placement location of the bond wires or the substrate. Additionally, by making the bond wire the contact of the packaged integrated circuit, the contact reduces parasitics (e.g., capacitance, inductance, etc.) associated with transitions and discontinuities between electrical conductors, (e.g, a transmission line to a bond wire, etc., are reduced or eliminated) and improves high-frequency electrical signal performance.

Although certain methods, apparatus, and articles of manufacture have been described herein, the scope of coverage of this patent is not limited thereto. On the contrary, this patent covers all apparatuses, methods and articles of manufacture fairly falling within the scope of the appended claims either literally or under the doctrine of equivalents.

What is claimed is:

1. A method of manufacturing a packaged integrated circuit, comprising:
attaching an integrated circuit to a substrate, the integrated circuit having a contact;
coupling a first end of a bond wire directly to the substrate and a second end of the bond wire to the contact of the integrated circuit;
encapsulating the integrated circuit and the bond wire; and
removing the substrate to expose the first end of the bond wire.

2. The method as defined in claim 1, wherein the substrate is removed via an etch process.

3. The method as defined in claim 1, wherein the first end of the bond wire forms the contact of the packaged integrated circuit.

4. The method as defined in claim 1, wherein coupling the bond wire directly to the substrate comprises coupling the bond wire to the substrate without an intervening bonding pad.

5. A method as defined in claim 1, wherein coupling the bond wire directly to the substrate comprises forming a stand-off-stitch bond.

6. The method as defined in claim 5, wherein forming a stand-off-stitch bond comprising the bond wire to form a stud on a fudicial marking of the substrate, and securing a bond wire to the stud.

7. The method as defined in claim 6, wherein the stud comprises a first material and wherein the bond wire comprises a second material.

8. The method as defined in claim 6, wherein the stud comprises a material having a first diameter and the bond wire comprises the material having a second diameter.

9. The method as defined in claim 6, wherein securing a bond wire to the stud comprises placing a bond wire from the integrated circuit to the stud.

10. The method as defined in claim 6, wherein securing a bond wire to the stud comprises placing a bond wire from the stud to the integrated circuit.

11. The method as defined in claim 1, wherein the substrate has a plurality of fudicial marks.

12. The method as defined in claim 1, wherein attaching the integrated circuit to a substrate comprises attaching a heat sink to the substrate and attaching the integrated circuit to the heat sink.

13. The method as defined in claim 1, wherein the substrate comprises a first material and the bond wire comprises a second material.

14. A packaged integrated circuit, comprising:
an integrated circuit having a contact;
a bond wire coupled to the contacts; and
a mold substantially containing the integrated circuit and the bond wire, the mold exposing an end of the bond wire to thereby form a contact of the packaged integrated circuit.

15. The packaged integrated circuit as defined in claim 14, wherein a substrate is removed to expose the end of the bond wire.

16. The packaged integrated circuit as defined in claim 15, wherein the substrate is removed by an etch process.

17. The packaged integrated circuit as defined in claim 14, further comprising a heat sink to dissipate the heat associated with the integrated circuit.

18. The packaged integrated circuit as defined in claim 17, wherein the heat sink is exposed on a surface of the packaged integrated circuit.

19. An electronic system, comprising:
a circuit board; and
at least one packaged integrated circuit comprising an integrated circuit with a contact, a bond wire, and a mold to contain the integrated circuit and the bond wire while exposing an end of the bond wire form a contact of the packaged integrated circuit.

20. The electronic system as defined in 19, wherein the packaged integrated circuit is attached to the circuit board via the contact of the packaged integrated circuit.

21. The electronic system as defined in 19, wherein the packaged integrated circuit is attached to the circuit board via solder.
